(19) United States
(12) Patent Application Publication
(10) Pub. No.: US 2013/0220545 A1
(43) Pub. Date: Aug. 29, 2013

(54) SUBSTRATE MOUNTING TABLE AND PLASMA ETCHING APPARATUS

(71) Applicant: Tokyo Electron Limited, (US)

(72) Inventors: Katsuyuki Koizumi, Kurokawa-gun (JP); Takehiro Ueda, Kurokawa-gun (JP)

(73) Assignee: TOKYO ELECTRON LIMITED, Tokyo (JP)

(21) Appl. No.: 13/774,037

(22) Filed: Feb. 22, 2013

Related U.S. Application Data
(60) Provisional application No. 61/605,930, filed on Mar. 2, 2012.

(30) Foreign Application Priority Data
Feb. 24, 2012 (JP) 2012-038734

(51) Int. Cl. H01L 21/683

(52) U.S. Cl. CPC H01L 21/6833
USPC 156/345.27; 279/128

(57) ABSTRACT

A substrate mounting table and a plasma etching apparatus can supply a power to a temperature controlling heater electrode effectively while preventing atmosphere from being leaked and preventing processing uniformity in a surface of a substrate from being deteriorated. The substrate mounting table and the plasma etching apparatus include an insulating member having therein an electrostatic chuck electrode and a temperature controlling heater electrode; a plate-shaped temperature controlling member having therein a temperature controlling medium path through which a temperature controlling medium is circulated; a cylindrical member made of an insulating material and provided within a through hole formed in the plate-shaped temperature controlling member; and a lead line, provided within the cylindrical member, having one end connected to the temperature controlling heater electrode and the other end connected to a connecting terminal provided at a bottom surface side of the cylindrical member.

### CROSS-REFERENCE TO RELATED APPLICATION

This application claims the benefit of Japanese Patent Application No. 2012-038734 filed on Feb. 24, 2012, and U.S. Provisional Application Ser. No. 61/605,930 filed on Mar. 2, 2012, the entire disclosures of which are incorporated herein by reference.

### Field of the Invention

The present disclosure relates to a substrate mounting table and a plasma etching apparatus.

### BACKGROUND OF THE INVENTION

Conventionally, in a manufacturing process of a semiconductor device, there has been used a plasma processing apparatus configured to perform a plasma process such as thin film forming process or etching process on a processing target substrate by allowing plasma excited from a processing gas to act on the processing target substrate (semiconductor wafer). In this plasma processing apparatus, a substrate mounting table (susceptor) configured to hold a substrate thereon is used. The substrate mounting table is disposed within a processing chamber of which inside is evacuated to a vacuum atmosphere. Further, it is also known that a temperature controlling heater electrode for controlling a temperature of a substrate is embedded in the substrate mounting table (see, for example, Patent Document 1).

FIG. 5 illustrates a configuration example of a conventional substrate mounting table having a temperature controlling heater electrode embedded therein. FIG. 5(a) is an enlarged view illustrating major components of a substrate mounting table 10, and FIG. 5(b) is an enlarged view illustrating a power supply unit 50 of FIG. 5(a). As depicted in FIG. 5, the substrate mounting table 10 includes a RF plate 40 for applying a high frequency power; a cooling plate 41 having a temperature controlling medium path 43 through which a temperature controlling medium is circulated; and a ceramic plate 42. The RF plate 40, the cooling plate 41 and the ceramic plate 42 are stacked on top of each other in sequence from the bottom. Embedded in the ceramic plate 42 are an electrostatic chuck electrode 44 and a temperature controlling heater electrode 45.

A power supply pin 51 is in contact with the temperature controlling heater electrode 45 from below the substrate mounting table 10 through a through hole 46 formed in the RF plate 40 and a through hole 47 formed in the cooling plate 41, and the power supply pin 51 supply a power to the temperature controlling heater electrode 45. In this configuration, the power supply pin 51 needs to be in firm contact with the temperature controlling heater electrode 45. For the purpose, the power supply pin 51 is pressed upward by a coil spring 52, so that the power supply pin 51 comes into firm contact with the temperature controlling heater electrode 45 while being pressurized thereto.

Patent Document 1: Japanese Patent Laid-open Publication No. H07-283292

In the conventional substrate mounting table as stated above, by bringing the power supply pin into the temperature controlling heater electrode embedded in the ceramic plate while the power supply pin is pressurized to the temperature controlling heater electrode, an electric conduction state therebetween is achieved.

In the substrate mounting table having the above-described configuration, however, the ceramic plate is fastened to the cooling plate by an adhesive or the like. Accordingly, if the power supply pin presses the temperature controlling heater electrode, a part of the ceramic plate may be detached from the cooling plate. As a result, if a gap is formed between the ceramic plate and the cooling plate, atmosphere may leak through the gap. Further, the temperature of the substrate may not be controlled uniformly, so that processing uniformity in the surface of the substrate is deteriorated.

### BRIEF SUMMARY OF THE INVENTION

In view of the foregoing problem, an illustrative embodiment provides a substrate mounting table and a plasma etching apparatus capable of supplying a power to a temperature controlling heater electrode effectively while preventing atmosphere from being leaked and preventing processing uniformity in a surface of a substrate from being deteriorated.

In accordance with one aspect of an illustrative embodiment, there is provided a substrate mounting table including an insulating member having therein an electrostatic chuck electrode configured to attract a substrate and a temperature controlling heater electrode; a plate-shaped temperature controlling member having therein a temperature controlling medium path through which a temperature controlling medium is circulated; a cylindrical member made of an insulating material and provided within a through hole formed in the plate-shaped temperature controlling member; and a lead line, provided within the cylindrical member, having one end connected to a first electrode terminal fastened to the temperature controlling heater electrode and the other end connected to a second electrode terminal provided at a bottom surface side of the cylindrical member.

In accordance with another aspect of the illustrative embodiment, there is provided a plasma etching apparatus including a processing chamber which is evacuable to a vacuum atmosphere; an etching gas supply unit configured to supply an etching gas into the processing chamber; a gas exhaust unit configured to evacuate an inside of the processing chamber; a plasma generating unit configured to generate plasma of the etching gas; and a substrate mounting table that is disposed within the processing chamber and configured to hold a substrate thereon. Further, the substrate mounting table includes an insulating member having therein an electrostatic chuck electrode configured to attract a substrate and a temperature controlling heater electrode; a plate-shaped temperature controlling member having therein a temperature controlling medium path through which a temperature controlling medium is circulated; a cylindrical member made of an insulating material and provided within a through hole formed in the plate-shaped temperature controlling plate-shaped member; and a lead line, provided within the cylindrical member, having cue end connected to a first electrode terminal fastened to the temperature controlling heater electrode and the other end connected to a second electrode terminal provided at a bottom surface side of the cylindrical member.

In accordance with the illustrative embodiment, it is possible to provide the substrate mounting table and the plasma etching apparatus capable of supplying a power to the temperature controlling heater electrode effectively while preventing atmosphere front being leaked and preventing processing uniformity in the surface of the substrate from being deteriorated.

### BRIEF DESCRIPTION OF THE DRAWINGS

Non-limiting and non-exhaustive embodiments will be described in conjunction with the accompanying drawings. Understanding that these drawings depict only several embodiments in accordance with the disclosure and are, therefore, not to be intended to limit its scope, the disclosure will be described with specificity and detail through use of the accompanying drawings, in which:

FIG. 1 is a diagram illustrating a schematic configuration of a plasma etching apparatus in accordance with an illustrative embodiment;

FIG. 2 is a diagram illustrating a schematic configuration of a substrate mounting table in accordance with the illustrative embodiment;

FIG. 3 is a diagram illustrating a schematic configuration of a power supply unit of the substrate mounting table in accordance with the illustrative embodiment;

FIG. 4 is a diagram illustrating a schematic configuration of a power supply unit of a substrate mounting table in accordance with a modification example; and

FIG. 5 is a diagram illustrating a schematic configuration of a conventional substrate mounting table.

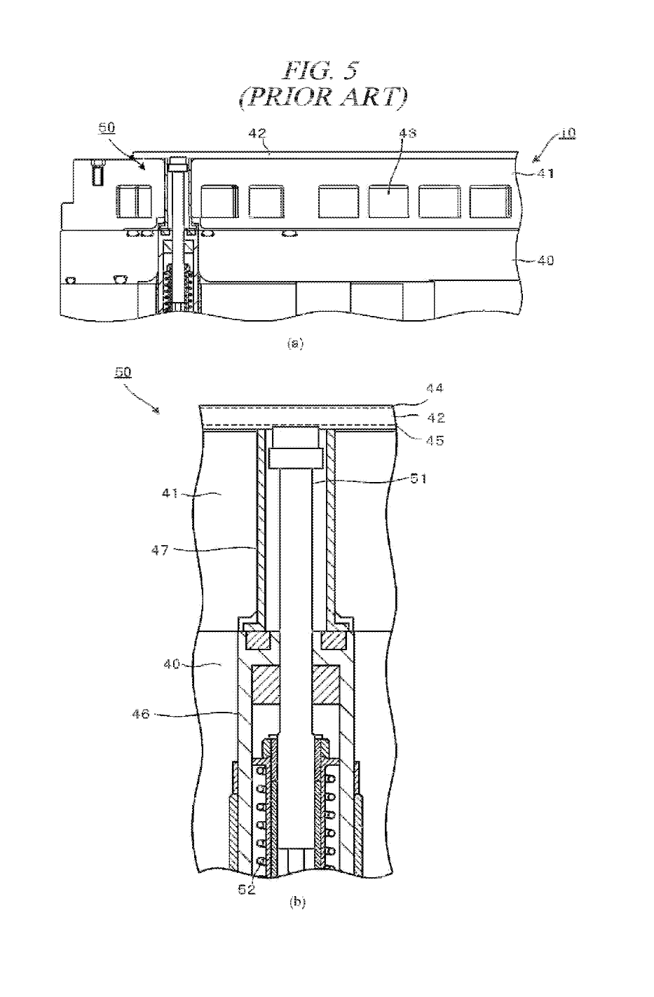

### DETAILED DESCRIPTION OF THE INVENTION

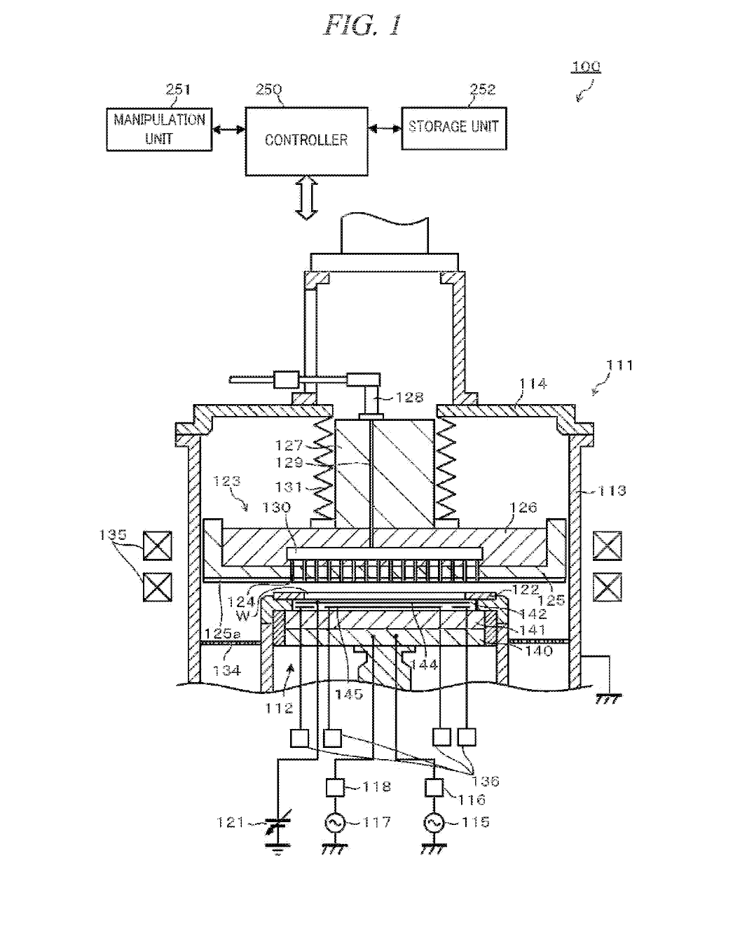

Hereinafter, illustrative embodiments will be described with reference to the accompanying drawings. FIG. 1 is a diagram illustrating a schematic configuration of a plasma etching apparatus in accordance with an illustrative embodiment. A plasma etching apparatus 100 shown in FIG. 1 includes a hermetically sealed cylindrical processing chamber 111 (cylindrical vessel) for accommodating therein a semiconductor wafer W having a diameter of, e.g., about 300 mm. A circular plate-shaped substrate mounting table 112 for mounting thereon the semiconductor wafer W is disposed at a lower portion of the processing chamber 111. The processing chamber 111 has a cylindrical sidewall 113 and a circular plate-shaped cover 114 that covers an upper end portion of the sidewall 113.

Further, an annular baffle plate 134 having a multiple number of gas exhaust holes is placed around the substrate mounting table 112 within the processing chamber 111. A gas exhaust device such as a non-illustrated TMP (Turbo Molecular Pump) or a DP (Dry Pump) is connected to a bottom of the processing chamber 111. Evacuation is performed through the baffle plate 134 so that an inside of the processing chamber 11 may be maintained in a depressurized atmosphere.

A first high frequency power supply 115 is connected to the substrate mounting table 112 via a first matching device 116, and a second high frequency power supply 117 is also connected to the substrate mounting table 112 via a second matching device 118. The first high frequency power supply 115 applies a high frequency power having a relatively high frequency for plasma generation ranging from, e.g., about 80 MHz to about 150 MHz (in the present illustrative embodiment, about 100 MHz) to the substrate mounting table 112. The second high frequency power supply 117 applies a high frequency bias power having a frequency lower than that of the first high frequency power supply 115 to the substrate mounting table 112. In accordance with the present illustrative embodiment, the frequency of the second high frequency power supply 117 is set to be, e.g., about 13.56 MHz.

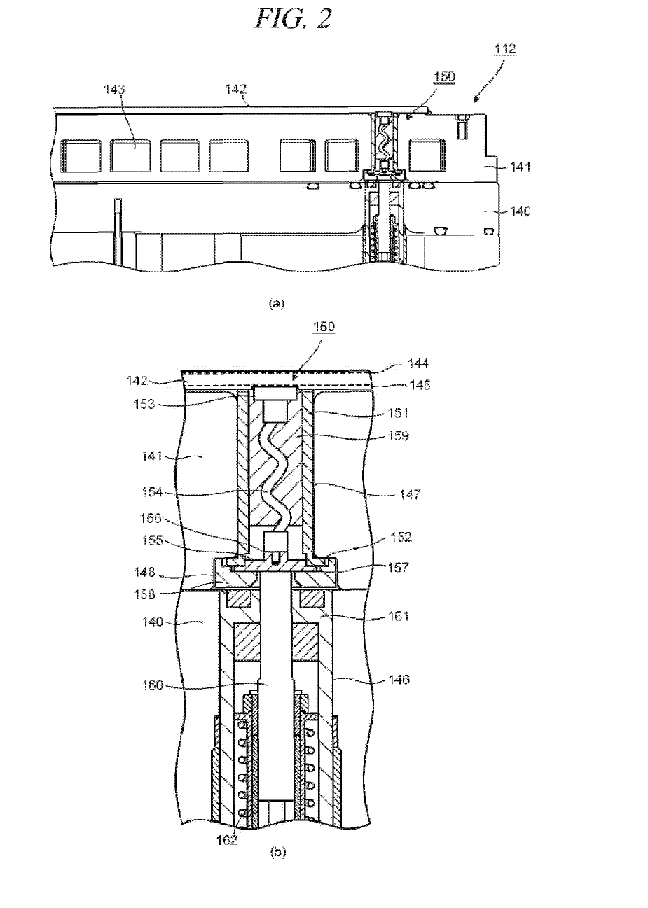

The substrate mounting table 112 includes a RF plate 140 for applying a high frequency power; a cooling plate 141 having a temperature controlling medium path 143 (see FIG. 2) through which a temperature controlling medium is circulated; and a ceramic plate 142. The RF plate 140, the cooling plate 141 and the ceramic plate 142 are stacked on top of each other in sequence from the bottom. Embedded in the ceramic plate 142 are an electrostatic chuck electrode 144 and temperature controlling heater electrodes 145.

A DC power supply 121 is connected to the electrostatic chuck electrode 144. If a positive DC voltage is applied to the electrostatic chuck electrode 144, a negative electric potential is generated in a rear surface of the semiconductor wafer W, so that an electric field is generated between the electrostatic chuck electrode 144 and the rear surface of the semiconductor wafer W. The semiconductor wafer W is attracted to and held on the substrate mounting table 112 by, e.g., a Coulomb force generated by the electric field.

The temperature controlling heater electrodes 145 are divided in two: a central electrode for heating a central portion of the semiconductor wafer W and a peripheral electrode for heating a periphery portion of the semiconductor wafer W. Heater power supplies 136 are connected to the temperature controlling heater electrodes 145. Further, a focus ring 122 is provided on the substrate mounting table 112 to surround the semiconductor wafer W held on the substrate mounting table 112. The focus ring 122 is made of, but not limited to, quartz.

A shower head 123 (moving electrode) is disposed at an upper portion of the processing chamber 111 to face the substrate mounting table 112. The shower head 123 includes a circular-plate shaped conductive upper electrode plate 125 having a multiple number of gas holes 124; a cooling plate 126 detachably fastened to the upper electrode plate 125; and a shaft 127 supporting the cooling plate 126; and a processing gas accommodating unit 128 provided at an upper end of the shaft 127. The shower head 123 is grounded via the cover 114 and the sidewall 113 and serves as a grounding electrode against a plasma generating power applied into the processing chamber 111. Further, a quartz member 125a is placed on the upper electrode plate 125 to cover a surface of the upper electrode plate 125 facing the substrate mounting table 112.

A gas flow path 129 is formed through the shaft 127 in a vertical direction. The cooling plate 126 has therein a buffer room 130. The gas flow path 129 connects the processing gas accommodating unit 123 with the buffer room 130, and each of the gas holes 124 communicates the buffer room 130 and an inside of the processing chamber 111. In the shower head 123, the gas holes 124, the processing gas accommodating unit 128, the gas flow path 129 and the buffer room 130 form a processing gas introducing system. This processing gas introducing system introduces a processing gas (etching gas) supplied into the processing gas accommodating unit 128 into a processing space between the shower head 123 and the substrate mounting table 112 within the processing chamber 111.

In the shower head 123, since an outer diameter of the upper electrode plate 125 is set to be slightly smaller than an inner diameter of the processing chamber 111, the shower head 123 is not in contact with the sidewall 113. That is, the shower head 123 is inserted into the processing chamber 111 with a clearance from the sidewall of the processing chamber 111. Further, the shaft 127 is configured to penetrate the cover 114, and a top portion of the shaft 127 is connected to a non-illustrated lift unit disposed above the plasma etching apparatus 100. The lift unit moves the shaft 127 up and down, so that the shower head 123 is moved like a piston within the processing chamber 111 along a central axis thereof. Accordingly, a gap between the shower head 123 and the substrate mounting table 112, i.e., a height of the processing space therebetween can be adjusted.

A bellows 131 is an expansible/contractible pressuring partition wall made of, but not limited to, stainless steel. One end of the bellows 131 is connected to the cover 114 while the other end thereof is connected to the shower head 123. The bellows 131 functions to seal the inside of the processing chamber 111 against an outside of the processing chamber 111. Further, annular magnets 135 are disposed outside the processing chamber 111 and configured to form a magnetic field within the processing chamber 111.

In the plasma etching apparatus 100, an etching gas supplied into the processing gas accommodating unit 128 is introduced into the processing space via the processing gas introducing system. The introduced etching gas is excited into plasma by a high frequency power applied into the processing space and a magnetic field formed by the magnets 135. Positive ions in the plasma may be attracted toward the semiconductor wafer W mounted on the substrate mounting table 112 by a negative bias potential generated by a bias power applied to the substrate mounting table 112. As a result, an etching process is performed on the semiconductor wafer W.

An overall operation of the plasma etching apparatus 100 having the above-described configuration is controlled by a controller 250 having a CPU and the like. The controller 250 includes a manipulation unit 251 and a storage unit 252.

The manipulation unit 251 includes a keyboard through which a process manager inputs commands to manage the plasma etching apparatus 100; a display that visually displays an operational status of the plasma etching apparatus 100; and so forth.

The storage unit 252 stores therein control programs (software) for implementing various processes performed in the plasma etching apparatus 100 under the control of the controller 250; or recipes including processing condition data and the like. In response to an instruction from the manipulation unit 251 or the like, a necessary recipe is retrieved from the storage unit 252 and executed by the controller 250, so that a desired process is performed in the plasma etching apparatus 100 under the control of the controller 250. The control programs or the recipes including the processing condition data can be used while being stored in a computer-readable storage medium (e.g., a hard disk, a CD, a flexible disk, a semiconductor memory, or the like), or can be used on-line by being received from another apparatus through, e.g., a dedicated line, whenever necessary.

Now, a sequence for performing the plasma etching process on a thin film formed on a semiconductor wafer W by using the plasma etching apparatus 100 having the above-described configuration will be explained. First, after a non-illustrated gate valve of the processing chamber 111 is opened, the semiconductor wafer W is loaded into the processing chamber 111 via a non-illustrated load lock chamber by a non-illustrated transfer robot or the like, and then, mounted on the substrate mounting table 112. Then, the transfer robot is retreated out of the processing chamber 111, and the gate valve is closed. Thereafter, the inside of the processing chamber 111 is evacuated by a non-illustrated gas exhaust device.

After the inside of the processing chamber 11 is evacuated to a certain vacuum level, an etching gas is introduced into the processing chamber 111 from the processing gas introducing system, and the inside of the processing chamber 111 is maintained at a certain pressure, e.g., about 13.3 Pa (about 100 mTorr). In this state, high frequency powers are applied to the substrate mounting table 112 from the first high frequency power supply 115 and the second high frequency power supply 117. At this time, a DC voltage is also applied to the electrostatic chuck electrode 144 from the DC power supply 121, and the semiconductor wafer W is attracted to and held on the substrate mounting table 112 by a Coulomb force or the like.

Further, as the high frequency powers are applied to the substrate mounting table 112, an electric field is generated between the shower head 123 serving as an upper electrode and the substrate mounting table serving as a lower electrode. Accordingly, electric discharge may be generated in the processing space where the semiconductor wafer W is placed. As a result, plasma etching is performed on the semiconductor wafer W by plasma excited from the etching gas.

After the plasma process is finished, the supply of the high frequency powers and the supply of the etching gas are stopped, and the semiconductor wafer W is unloaded from the processing chamber 111 in the reverse sequence to that described above.

Now, a detailed configuration of the substrate mounting table 112 will be explained. FIG. 2(a) is an enlarged view illustrating major components of the substrate mounting table 112, and FIG. 2(b) is an enlarged view of a power supply unit 150 of FIG. 2(a). As shown in FIG. 2, the substrate mounting table 112 includes the RF plate 140 for applying a high frequency power; the cooling plate 141 having the temperature controlling medium path 143 through which a temperature controlling medium is circulated; and the ceramic plate 142. The RF plate 140, the cooling plate 141 and the ceramic plate 142 are stacked on top of each other in sequence from the bottom. The electrostatic chuck electrode 144 and the temperature controlling heater electrodes 145 are embedded in the ceramic plate 142. Although only one power supply unit 150 is illustrated in FIG. 2, a total of four power supply units 150 may be provided. That is, two power supply units 150 are connected to the temperature controlling heater electrode 145 for heating the central portion of the semiconductor wafer W, and the other two power supply units 150 are connected to the temperature controlling heater electrode 145 for heating the periphery portion of the semiconductor wafer W.

With this configuration, power is supplied to the temperature controlling heater electrodes 145 from below the substrate mounting table 112 by the power supply units 150 via a through hole 146 formed in the RF plate 140 and a through hole 147 formed in the cooling plate 141.

Each of the cower supply units 150 has a cylindrical member 151 inserted and fixed in the through hole 147 of the cooling plate 141. The cylindrical member 151 is made of an insulating material. An outwardly extending flange 152 is formed at a lower end portion of the cylindrical member 151. Meanwhile, a large-diameter portion 148 having a diameter larger than that of the through hole 147 is formed at a lower end portion of the through hole 147 of the cooling plate 141. As the flange 152 is engaged with a step-shaped portion between the large-diameter portion 148 and the through hole 147, the cylindrical member 151 has an aligned position within the through hole 147. The cylindrical member 151 is fixed in the through hole 147 by, e.g., an adhesive.

A heater-side electrode terminal 153 is provided within the cylindrical member 151. The heater-side electrode terminal 153 is connected to the temperature controlling heater electrodes 145 made of, e.g., indium. A lead line 154 is fixed to a lower side of the heater-side electrode terminal 153, and a lower end portion of the lead line 154 is fixed to a power supply-side electrode terminal 155. The lead line 154 is curved between the heater-side electrode terminal 153 and the power supply-side electrode terminal 155.

The power supply-side electrode terminal 155 has a small-diameter portion 156 at an upper part thereof and a large-diameter portion 157 at a lower part thereof. The small-diameter portion 156 is inserted into the cylindrical member 151, and the large-diameter portion 157 is engaged with the flange 152. Accordingly, the power supply-side electrode terminal 155 is aligned with respect to the cylindrical member 151 and is fixed from below by an annular fixing member 158 made of an insulating material.

Here, in order to prevent abnormal discharge between the cooling plate 141 and the lead line 154 from occurring, a gap between the cooling plate 141 and the lead line 154 needs to be large to a certain level by setting the diameter of the cylindrical member 151 to be large. With this configuration, however, since the power supply unit 150 is scaled up, the diameter of the through hole 147 of the cooling plate 141 also needs to be increased. Due to the increase of the diameter of the through hole 147, however, cooling efficiency and temperature uniformity may be deteriorated, so that processing uniformity in the surface of the semiconductor wafer W may be reduced.

As a solution, in accordance with the present illustrative embodiment, a filling material 159 such as insulating resin is filled in the upper space within the cylindrical member 151. By filling the filling material 159, it is possible to effectively prevent abnormal discharge between the cooling plate 141 and the lead line 154 or the like from occurring. Further, since the cooling plate 141 is cooled and the ceramic plate 142 is heated, the cooling plate 141 would be contracted while the ceramic plate 142 would be expanded. Accordingly, a stress would be applied to the filling material 159 due to such contraction and expansion. Thus, it may be desirable to use rein having flexibility as the filling material 159.

A pin-shaped terminal (power supply terminal) 160 is in contact with a bottom surface of the power supply-side electrode terminal 155. The pin-shaped terminal (power supply terminal) 160 is accommodated in a cylindrical tube-shaped member 161 made of an insulating material. A coil spring 162 is provided within the tube-shaped member 161, and an upper end portion of the pin-shaped terminal (power supply terminal) 160 is brought into pressurized contact with the bottom surface of the power supply-side electrode terminal 155 by being pressed through the coil spring 162.

As described above, since the pin-shaped terminal (power supply terminal) 160 and the power supply-side electrode terminal 155 are in pressurized contact with each other, an electric conduction state therebetween can be securely obtained. Further, since a pressing force to the power supply-side electrode terminal 155 is received by the step-shaped portion at the large-diameter portion 148 of the through hole 147 within the cooling plate 141, the pressing force may not be applied so the ceramic plate 142. As a result, it is possible to prevent the ceramic plate 142 and the cooling plate 141 from being separated. Thus, it is possible to prevent leakage of the atmosphere and deterioration of the processing uniformity in the surface of the semiconductor wafer W due to non-uniform temperature of the semiconductor wafer W from occurring.

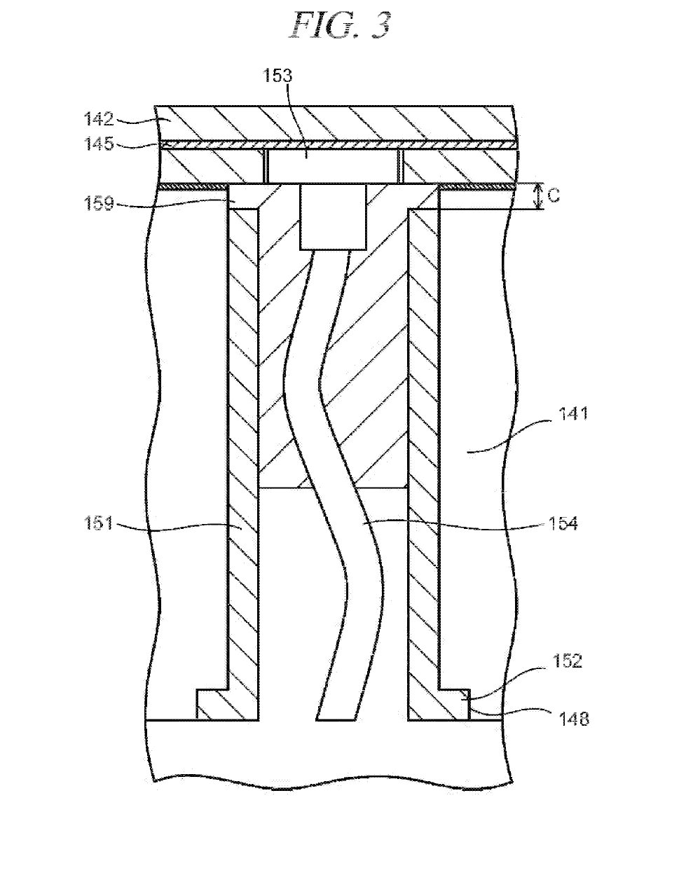

FIG. 3 is a schematic enlarged view illustrating a positional relationship between the cooling plate 141 and the ceramic plate 142. As depicted in FIG. 3, the cylindrical member 151 is aligned as the flange 152 formed at the lower end portion of the cylindrical member 151 is engaged with the step-shaped portion between the large-diameter portion 148 and the through hole 147. Here, an upper end portion of the cylindrical member 151 is not in contact with the ceramic plate 142. That is, a gap C is formed between the upper end portion of the cylindrical member 151 and a bottom surface of the ceramic plate 142. Desirably, this gap C may be set to range from, e.g., about 0.5 mm to about 1.5 mm, and, more desirably, set to be, e.g., about 1 mm. Furthermore, a large-diameter portion formed at an upper portion of the heater-side electrode terminal 153 may be set to have an appropriate thickness (e.g., about 0.5 mm to about 1.0 mm) not to be extended lower than the bottom surface of the ceramic plate 142.

The filling material 159 filled in the cylindrical member 151 is also filled in the gap C between the upper end portion of the cylindrical member 151 and the bottom surface of the ceramic plate 142. As stated above, when the ceramic plate 142 is expanded and the cooling plate 141 is contracted, the filling material 159 filled in the gap C would be deformed, so that the filling material 159 can absorb a stress generated by such expansion and contraction. Here, if a material (solid material) without having flexibility is used as the filling material 159, the stress generated by the expansion and contraction would be applied to a joint portion between the temperature controlling heater electrode 145 and the heater-side electrode terminal 153, and the connection state therebetween may become poor. In such a case, electrical resistance may be increased, so that a certain burning may occur.

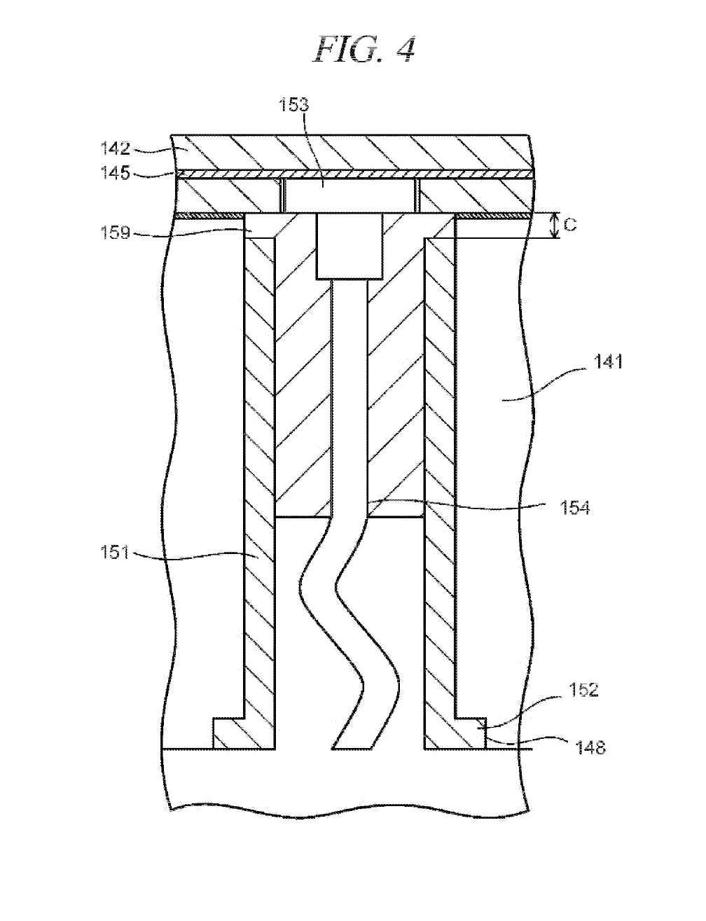

In the example shown in FIG. 3, the entire lead line 154 is curved. However, as illustrated in FIG. 4, a part of the lead line 154 embedded in the filling material 159 may have a straight line shape, and the other part of the lead line 154 located outside the filling material 159 may be curved. If the part of the lead line 154 embedded in the filling material 159 is formed in the straight line shape, the distance between the cooling plate 141 and the lead line 154 can be maintained maximum at the straight line-shaped portion of the lead line 154. Thus, the possibility of occurrence of abnormal discharge between the cooling plate 141 and the lead line 154 can be further reduced.

Further, the present disclosure is not limited to the above illustrative embodiment and modification, and can be variously modified.

What is claimed is:

1. A substrate mounting table comprising:
an insulating member having therein an electrostatic chuck electrode configured to attract a substrate and a temperature controlling heater electrode;
a plate-shaped temperature controlling member having therein a temperature controlling medium path through which a temperature controlling medium is circulated;
a cylindrical member made of an insulating material and provided within a through hole formed in the plate-shaped temperature controlling member; and
a lead line, provided within the cylindrical member, having one end connected to a first electrode terminal fastened to the temperature controlling heater electrode and the other end connected to a second electrode terminal provided at a bottom surface side of the cylindrical member.

2. The substrate mounting table of claim 1,
wherein a flange is formed at a lower end portion of the cylindrical member, and
the flange is engaged with the plate-shaped temperature controlling member.

3. The substrate mounting table of claim 1, further comprising:
a power supply unit having a power supply terminal which is electrically connected with the second electrode terminal from below the second electrode terminal while being pressurized to the second electrode,
wherein a power is supplied to the temperature controlling heater electrode from the power supply unit.

4. The substrate mounting table of claim 1,
wherein a resin is filled in a part of an inside of the cylindrical member at a side of the insulating member.

5. The substrate mounting table of claim 1,
wherein a gap is provided between an end portion of the cylindrical member and the insulating member, and
a resin is filled in the gap.

6. The substrate mounting table of claim 1,
wherein a part of the lead line at a side of the temperature controlling heater electrode is formed in a straight line shape, and the other part of the lead line is curved.

7. The substrate mounting table of claim 4,
wherein a part of the lead line, the part being embedded in the resin, is formed in a straight line shape, and the other part of the lead line is curved.

8. A plasma etching apparatus comprising:
a processing chamber which is evacuable to a vacuum atmosphere;
an etching gas supply unit configured to supply an etching gas into the processing chamber;
a gas exhaust unit configured to evacuate an inside of the processing chamber;
a plasma generating unit configured to generate plasma of the etching gas; and
a substrate mounting table that is disposed within the processing chamber and configured to hold a substrate thereon,
wherein the substrate mounting table comprises:
an insulating member having therein an electrostatic chuck electrode configured to attract a substrate and a temperature controlling heater electrode;
a plate-shaped temperature controlling member having therein a temperature controlling medium path through which a temperature controlling medium is circulated;
a cylindrical member made of an insulating material and provided within a through hole formed in the plate-shaped temperature controlling plate-shaped member; and
a lead line, provided within the cylindrical member, having one end connected to a first electrode terminal fastened to the temperature controlling heater electrode and the other end connected to a second electrode terminal provided at a bottom surface side of the cylindrical member.
